(19) United States
(12) Patent Application Publication
(10) Pub. No.: US 2020/0265969 A1
(43) Pub. Date: Aug. 20, 2020

(54) OXIDATION-RESISTANT HYBRID STRUCTURE COMPRISING METAL THIN FILM LAYER COATED ON EXTERIOR OF CONDUCTIVE POLYMER STRUCTURE, AND PREPARATION METHOD THEREFOR

(71) Applicants: AJOU UNIVERSITY INDUSTRY-ACADEMIC COOPERATION FOUNDATION, Gyeonggi-do (KR); ELPANI CO., LTD., Gyeonggi-do (KR)

(72) Inventors: Suck Hyun Lee, Gyeonggi-do (KR); O Pil Kwon, Gyeonggi-do (KR); Myung Jo Jung, Gyeonggi-do (KR); Tae Ja Kim, Gyeonggi-do (KR)

(73) Assignees: AJOU UNIVERSITY INDUSTRY-ACADEMIC COOPERATION FOUNDATION, Gyeonggi-do (KR); ELPANI CO., LTD., Gyeonggi-do (KR)

(21) Appl. No.: 16/347,369

(22) PCT Filed: Nov. 3, 2017
(86) PCT No.: PCT/KR2017/012411

§ 371 Date: Jul. 18, 2019

(30) Foreign Application Priority Data
Nov. 4, 2016 (KR) 10-2016-0147037

(51) Int. Cl. H01B 1/12; H05K 9/00; C23C 18/16; C23C 18/40; H01M 8/0206; H01M 8/0221; H01M 8/0228; C09D 11/52

(52) U.S. Cl. CPC H01B 1/128; H05K 9/0088; C23C 18/1641; C23C 18/1646; C09D 11/52; C23C 18/40; H01M 8/0206; H01M 8/0221; H01M 8/0228; C23C 18/1666

(57) ABSTRACT

The present disclosure relates to an oxidation-resistant and/or corrosion-resistant hybrid structure including a metal layer (thin film layer) coated on the exterior of a conductive polymer structure, and a preparation method for the hybrid structure.

### TECHNICAL FIELD

The present disclosure relates to an oxidation-resistant and/or corrosion-resistant hybrid structure including a metal layer (thin film layer) coated on the exterior of a conductive polymer structure, and a preparation method for the hybrid structure.

### BACKGROUND

Recently, as the world has entered the information age, chemically stable nanometal materials have attracted a lot of attention as materials that enable the miniaturization, weight lightening, and wearability in the fields of conductive inks, 3-D printing, biomedical implants, transparent electrodes, fuel cells, and MEMS. In general, inherently conducting polymers (ICPs) contain conjugated double bonds in their main chains and are not dissolved well in typical organic solvents and not thermally melted. The polymers have received attention due to their electrochemical characteristics for suppressing corrosion of metals in addiction to conductivity from early stages of development. Particularly, a polyaniline has received a lot of attention because it is lighter and cheaper than metals and stable in air and is known as being most effective in suppressing corrosion among the conductive polymers. The conductive polymers are known as having a simple barrier effect of forming a coated film with a polymer to suppress corrosion of a metal in addition to an anodic protection effect caused by charge transfer between the metal and the polymer. Anodic protection occurs when the metal is oxidized and the conductive polymer is reduced so that the corrosion potential is shifted. However, study results reported to date have adopted a method of coating the surface of a metal with a conductive polymer to block contact with oxygen and also suppress corrosion by electrochemical mechanism. According to the above-described method, corrosion can be effectively suppressed, but the polymer coated on the metal causes a decrease in thermal and electrical conductivity and an increase in processing temperature for removing the polymer layer during sintering.

For example, recently published PCT/KR2012/009189 and US2015/0344715 disclose that oxidation-resistant copper particles produced by coating a polymer on copper particles are used to prepare an ink, and, thus, the ink can be stored under atmospheric conditions for 3 or more months. However, corrosion is not effectively suppressed, and since a large amount of the polymer is used to enhance oxidation resistance, a high-temperature process for removing the polymer is required during sintering. Also, when the ink is prepared with the oxidation-resistant copper particles, the conductivity decreases.

Further, US2012/0153239A1 discloses a conductive filler coated with a metal. However, the metal is coated not on a conductive polymer but on porous inorganic particles and thus can be oxidized on the surface.

Most of other conventional technologies relate to production of typical metal-conductive polymer composite materials. Chinese Patent CN101745646B discloses a method for preparing a metal-polyaniline nano-silver sol by performing aniline polymerization in a solution in which an aniline metal salt and an aniline are dissolved. The present disclosure is essentially quite different from the above-described inventions in that the above-described inventions disclose a simple mixture or a layer of a lot of metal particles or layers whose cross-section shows simple contact between the metal and a conductive polymer without distinction between interior and exterior, whereas the present disclosure discloses single particles produced by coating conductive polymer particles with a metal and exposing the metal layer to air.

According to A. Yabuki (Synth. Met. vol. 46 pp: 2323-2327, 2011), copper nanoparticles are oxidized (Cu₂O) at 150° C. and oxidized and rapidly converted into CuO at 300° C. Like copper, bulk metal has certain corrosion resistance, but nanoscale metal is easily corroded. Therefore, use of nanoscale metals are not easy.

Further, most of nanoscale metals show a decrease in melting point with a decrease in size, and, thus, their processing temperatures decrease to about plastic processing temperature. Therefore, they may be formed for various uses. However, they have corrosion problem as described above and have a serious problem of fatal high-temperature oxidation particularly during sintering. Further, when they are produced by dispersion, a stabilizer is used to stabilize particle surfaces. In this case, a polymer coated on the surfaces causes an increase in sintering temperature, which limits the uses thereof. The present disclosure provides a technology for solving the above-described problems of nanomaterials.

### DISCLOSURE OF THE INVENTION

### Problems to be Solved by the Invention

The present disclosure relates to an oxidation-resistant and/or corrosion-resistant hybrid structure including a metal layer (thin film) coated on a conductive polymer structure, and a preparation method for the hybrid structure.

Specifically, the conductive polymer structure whose surface is coated with the metal thin film of the present disclosure [hereinafter, also referred to as “MC-ICP” (metal-coated inherently conducting polymer particle)] is produced by coating a film of a metal such as copper on a surface of a structure, e.g., a spherical, needle-shaped, or fibrous conductive polymer, having a different aspect ratio to enhance corrosion resistance and oxidation resistance of metals vulnerable to corrosion or oxidation. Accordingly, there is no limit to a size of the structure, and if the structure is a spherical particle or fiber, its diameter may be from several nanometers to several hundreds of micrometers or more. Also, there is no limit to the aspect ratio of the fiber.

The present disclosure does not adopt a conventional method of coating a conductive polymer on a surface of a metal to protect the surface of the metal, but uses a metal as a surface layer coated on the exterior of a conductive polymer which is an internal polymer and determines the shape of a particle. Herein, the metal on the exterior means that the metal layer coated on the surface is exposed to external surrounding environment such as air or water. Therefore, the present disclosure describes that a hybrid particle including a conductive polymer coated inside a metal surface has the effect of suppressing corrosion of the metal.

However, problems to be solved by the present disclosure are not limited to the above-described problems. Although not described herein, other problems to be solved by the present disclosure can be clearly understood by a person with ordinary skill in the art from the following description.

### Means for Solving the Problems

A first aspect of the present disclosure provides a hybrid structure, including a metal thin film layer coated on a surface of a conductive polymer structure, wherein the hybrid structure imparts enhancement in oxidation resistance and/or corrosion resistance of the metal.

A second aspect of the present disclosure provides a conductive ink filler, an electromagnetic shielding agent, a fuel cell separator, an electrode, or a flexible electrode including the hybrid structure of the first aspect of the present disclosure.

A third aspect of the present disclosure provides a method for preparing the hybrid structure of the first aspect, including:

(a) forming a conductive polymer structure; and

(b) coating a metal on a surface of the conductive polymer structure by an electroless plating method for reducing a metal salt precursor using a solution containing the conductive polymer structure, the metal salt precursor, a reducing agent and a dispersion solvent to obtain a hybrid structure including a metal thin film layer coated on the surface of the conductive polymer structure.

### Effects of the Invention

According to embodiments of the present disclosure, a hybrid structure is formed by coating a conductive polymer even with a nanoscale (thickness) metal film so that corrosion and oxidation of the metal can be suppressed at high temperature. Further, the polymer and the metal can be thermally necked at a relatively low temperature, and, thus, it is easy to produce the hybrid structure. The conductive polymer is light and not well dissolved in an organic solvent and has high thermal stability and thus can maintain its shape while being coated with the metal. Therefore, the conductive polymer can serve as a thermal or electrical conductive filler. The hybrid structure does not have a high density and surface functional groups of the conductive polymer are exposed depending on the degree of coating of the metal layer, and, thus, it can be easily dispersed. Therefore, the hybrid structure has an advantage when it is used for producing a conductive ink or a plastic composite material. Further, the hybrid structure has conductivity due to the metal layer and can absorb near-infrared electromagnetic waves due to the conductive polymer core and thus also has the effect of shielding electromagnetic waves.

According to embodiments of the present disclosure, the hybrid structure includes a conductive polymer structure or particle whose surface is coated with a metal layer or thin film and is produced by coating a metal film such as copper on surface of a structure, e.g., a spherical, needle-shaped, or fibrous conductive polymer, having a different aspect ratio to enhance corrosion resistance and oxidation resistance of metals vulnerable to corrosion or oxidation. Although these particles includes the conductive polymer, such as a polyaniline, not on the surface of the metal layer but inside the metal, they have excellent oxidation resistance. Conductive polymer particles of various shapes may be prepared and then, a metal thin film may be coated on these particles by vacuum deposition, sputtering, and electroless plating. The nanoscale metal thin film coated partly or entirely on the surface of the conductive polymer particles becomes stabilized in air regardless of the thickness (from 1 nm to 100 nm) of the metal, such as copper vulnerable to corrosion. Therefore, it is possible to achieve weight lightening and miniaturization of electronic products. They can be used for conductive inks, anisotropic conductive films (ACF), fuel cell separators, and the like, and they can be necked at a low temperature of 300° C. or less and thus can be used for RFID, electrodes or flexible electrodes of organic electronic products such as a display, or the like, and electromagnetic shielding agents.

According to embodiments of the present disclosure, surface functional groups of the conductive polymer may serve as seeds for coating the metal film, and, thus, the metal particles can be uniformly coated on the surface of the conductive polymer.

### BRIEF DESCRIPTION OF THE DRAWINGS

FIG. 1 is a UV-vis-NIR spectrum of the synthesized emeraldine base (EB) according to an example of the present disclosure.

FIG. 2 is a FT-IR spectrum of the synthesized EB according to an example of the present disclosure.

FIG. 3 is a FE-SEM image of a rod-shaped emeraldine salt (ES) structure according to an example of the present disclosure.

FIG. 4 is a UV spectrum of a solution in ES-state according to an example of the present disclosure.

FIG. 5 is a FE-SEM image of a spherical ES structure according to an example of the present disclosure.

FIG. 6 is a TEM image of the prepared EB-Cu hybrid particles according to an example of the present disclosure.

FIG. 7 is an X-ray diffraction diagram of the prepared EB-Cu according to an example of the present disclosure.

FIG. 8 is a TGA graph of the prepared EB-Cu hybrid particles according to an example of the present disclosure.

FIG. 9 is an X-ray diffraction diagram of the prepared ES-coated Cu particles according to an example of the present disclosure.

FIG. 10 is a photo of the prepared EB-Cu sample after sintering according to an example of the present disclosure.

FIG. 11 is a FE-SEM image of the prepared EB-Cu sample after sintering according to an example of the present disclosure.

### BEST MODE FOR CARRYING OUT THE INVENTION

Hereafter, examples will be described in detail with reference to the accompanying drawings so that the present disclosure may be readily implemented by a person with ordinary skill in the art. However, it is to be noted that the present disclosure is not limited to the examples but can be embodied in various other ways. In the drawings, parts irrelevant to the description are omitted for the simplicity of explanation, and like reference numerals denote like parts through the whole document.

Throughout this document, the term “connected to” may be used to designate a connection or coupling of one element to another element and includes both an element being “directly connected to” another element and an element being “electronically connected to” another element via another element.

Through the whole document, the term “on” that is used to designate a position of one element with respect to another element includes both a case that the one element is adjacent to the other element and a case that any other element exists between these two elements.

Through the whole document, the term “comprises or includes” and/or “comprising or including” used in the document means that one or more other components, steps, operation and/or existence or addition of elements are not excluded in addition to the described components, steps, operation and/or elements unless context dictates otherwise. Through the whole document, the term “about or approximately” or “substantially” is intended to have meanings close to numerical values or ranges specified with an allowable error and intended to prevent accurate or absolute numerical values disclosed for understanding of the present disclosure from being illegally or unfairly used by any unconscionable third party. Through the whole document, the term “step of” does not mean “step for”.

Through the whole document, the term “combination(s) of” included in Markush type description means mixture or combination of one or more components, steps, operations and/or elements selected from a group consisting of components, steps, operation and/or elements described in Markush type and thereby means that the disclosure includes one or more components, steps, operations and/or elements selected from the Markush group.

A first aspect of the present disclosure provides a hybrid structure, including a metal thin film layer coated on a surface of a conductive polymer structure, wherein the hybrid structure imparts enhancement in oxidation resistance and/or corrosion resistance of the metal.

In an embodiment of the present disclosure, the hybrid structure is formed as a hybrid structure or particle produced by coating a metal on a surface of the conductive polymer structures or particles having different sizes and shapes, and oxidation of the metal thin film as a surface layer can be suppressed even at a high temperature of about 100° C. or more or about 150° C. or more, and the hybrid structure can be necked and sintered at a low temperature of about 200° C. or about 300° C. or less.

In an embodiment of the present disclosure, the conductive polymer structure whose surface is coated with the metal thin film layer [hereinafter, also referred to as “MC-ICP” (metal-coated inherently conducting polymer particle)] is produced by coating a film of a metal such as copper on a surface of a structure, e.g., a spherical, needle-shaped, or fibrous conductive polymer, having a different aspect ratio to enhance corrosion resistance and oxidation resistance of metals vulnerable to corrosion or oxidation. Accordingly, there is no limit to the size of the structure. For example, if the structure is a spherical particle or fiber having a specific size, its diameter may be from several nanometers to several hundreds of micrometers or more. Also, there is no limit to the aspect ratio of the fiber.

In an embodiment of the present disclosure, the conductive polymer includes a conductive polymer selected from the group consisting of a polyaniline, a polypyrrole, a polythiophene, poly(3,4-ethylenedioxythiophene), a polyacetylene, and combinations thereof. For example, the conductive polymer may not be limited to being in a specific oxidation state but may be in a doped or undoped state.

In an embodiment of the present disclosure, the conductive polymer may include a polyaniline and includes, for example, a conductive polymer selected from the group consisting of a polyaniline emeraldine base (EB), a polyaniline emeraldine salt (ES), and combinations thereof. For example, the conductive polymer may include a polyaniline emeraldine base (EB), a polyaniline emeraldine salt (ES) doped using various acids, or all of them depending on the doping state, but may not be limited thereto.

In an embodiment of the present disclosure, an aspect ratio of the conductive polymer structure is from about 1 to about 1,000. For example, the aspect ratio of the conductive polymer structure may be from about 1 to about 1,000, from about 10 to about 1,000, from about 50 to about 1,000, from about 100 to about 1,000, from about 200 to about 1,000, from about 300 to about 1,000, from about 400 to about 1,000, from about 500 to about 1,000, from about 600 to about 1,000, from about 700 to about 1,000, from about 800 to about 1,000, from about 900 to about 1,000, from about 1 to about 900, from about 1 to about 800, from about 1 to about 700, from about 1 to about 600, from about 1 to about 500, from about 1 to about 400, from about 1 to about 300, from about 1 to about 200, from about 1 to about 100, from about 1 to about 50, or from about 1 to about 10. Further, the conductive polymer structure may have all possible shapes such as spherical shape, oval shape, rod shape, nanorod shape, nanoneedle shape, nanofiber shape, and the like.

In an embodiment of the present disclosure, the metal includes a metal selected from the group consisting of copper, nickel, palladium, ruthenium, tin, lead, iron, stainless steel, gold, silver, and combinations thereof, but may not be limited thereto. For example, the metal includes copper as a main element, but may not be limited thereto.

In an embodiment of the present disclosure, a thickness of the metal thin film may be from about 1 nm to about 300 nm. For example, the thickness of the metal thin film may be from about 1 nm to about 300 nm, from about 10 nm to about 300 nm, from about 20 nm to about 300 nm, from about 40 nm to about 300 nm, from about 60 nm to about 300 nm, from about 80 nm to about 300 nm, from about 100 nm to about 300 nm, from about 120 nm to about 300 nm, from about 140 nm to about 300 nm, from about 160 nm to about 300 nm, from about 180 nm to about 300 nm, from about 200 nm to about 300 nm, from about 220 nm to about 300 nm, from about 240 nm to about 300 nm, from about 260 nm to about 300 nm, from about 280 nm to about 300 nm, from about 1 nm to about 280 nm, from about 1 nm to about 260 nm, from about 1 nm to about 240 nm, from about 1 nm to about 220 nm, from about 1 nm to about 200 nm, from about 1 nm to about 180 nm, from about 1 nm to about 160 nm, from about 1 nm to about 140 nm, from about 1 nm to about 120 nm, from about 1 nm to about 100 nm, from about 1 nm to about 80 nm, from about 1 nm to about 60 nm, from about 1 nm to about 40 nm, from about 1 nm to about 20 nm, or from about 1 nm to about 10 nm. Further, about 70% or more of all the hybrid structures may be coated with the metal layer having a thickness of from about 1 nm to about 300 nm.

In an embodiment of the present disclosure, the metal thin film layer is coated partly or entirely on the surface of the conductive polymer structure. For example, the metal thin film layer may be coated on from about 30% to about 100% of the surface of the hybrid structure. For example, the metal thin film layer may be coated on from about 30% to about 100%, from about 35% to about 100%, from about 40% to about 100%, from about 45% to about 100%, from about 50% to about 100%, from about 55% to about 100%, from about 60% to about 100%, from about 65% to about 100%, from about 70% to about 100%, from about 75% to about 100%, from about 80% to about 100%, from about 85% to about 100%, from about 90% to about 100%, from about 95% to about 100%, from about 30% to about 95%, from about 30% to about 90%, from about 30% to about 85%, from about 30% to about 80%, from about 30% to about 75%, from about 30% to about 70%, from about 30% to about 65%, from about 30% to about 60%, from about 30% to about 55%, from about 30% to about 50%, from about 30% to about 45%, from about 30% to about 40%, or from about 30% to about 35% of the surface of the hybrid structure.

In an embodiment of the present disclosure, the metal thin film layer has oxidation resistance and/or corrosion resistance at a high temperature of about 100° C. or more, about 150° C. or more, about 200° C., about 250° C. or more, or about 300° C. or more.

A second aspect of the present disclosure provides a conductive ink filler, an electromagnetic shielding agent, a fuel cell separator, an electrode, a flexible electrode, or a conductive filler for conductive plastic composite material including the hybrid structure of the first aspect of the present disclosure.

Detailed descriptions on a conductive ink filler, an electromagnetic shielding agent, a fuel cell separator, an electrode, a flexible electrode, or a conductive filler for conductive plastic composite material according to the second aspect of the present disclosure, which overlap with those of the first aspect of the present disclosure, are omitted hereinafter, but the descriptions of the first aspect of the present disclosure may be identically applied to the second aspect of the present disclosure, even though they are omitted hereinafter.

In embodiments of the present disclosure, the fuel cell separator may be a conductive plastic composite material formed by adding the hybrid structure, as a conductive filler, to a plastic substrate, and as the plastic, without particular limitation it may be used, any plastic that is used as a material of a separator in the field of fuel cells.

In embodiments of the present disclosure, the nanoscale metal thin film layer coated partly or entirely on the surface of the conductive polymer particles becomes stabilized in air regardless of the thickness (from 1 nm to 100 nm) of the metal, such as copper vulnerable to corrosion. Therefore, it is possible to achieve weight lightening and miniaturization of electronic products. They have high thermal and electrical conductivity which is a general property of metals and the lightness of plastics, and thus can be used for conductive inks, anisotropic conductive films (ACF), fuel cell separators, and the like, and they can be necked at a low temperature of 300° C. or less and thus can be used for RFID, electrodes or flexible electrodes of organic electronic products such as a display, or the like, thermoelectric materials for 3-D printing, heat-radiating materials, and various conductive circuit materials, and electromagnetic shielding agents.

A third aspect of the present disclosure provides a method for preparing the hybrid structure of the first aspect, including:

(a) forming a conductive polymer structure; and

(b) coating a metal on a surface of the conductive polymer structure by an electroless plating method for reducing a metal salt precursor using a solution containing the conductive polymer structure, the metal salt precursor, a reducing agent and a dispersion solvent to obtain a hybrid structure including a metal thin film layer coated on the surface of the conductive polymer structure.

Detailed descriptions of the method for preparing the hybrid structure according to the third aspect of the present disclosure, which overlap with those of the first aspect of the present disclosure, are omitted hereinafter, but the descriptions of the first aspect of the present disclosure may be identically applied to the third aspect of the present disclosure, even though they are omitted hereinafter.

In an embodiment of the present disclosure, the preparation method may further include pretreating the conductive polymer structure before the step (b).

In an embodiment of the present disclosure, a material used for the pretreating of the conductive polymer structure includes a material selected from the group consisting of a polyethylene glycol, a sodium polyacrylate, a polyvinylpyrrolidone, a poly(vinyl caprolactam), a poly(sodium 4-styrenesulfonate), SnCl₂, PdCl₂, and combinations thereof. The pretreating material serves to regulate the coating range of the metal thin film layer in the hybrid structure and stabilize the dispersion solvent.

In an embodiment of the present disclosure, the reducing agent used in step (b) is a weak reducing agent to assist to uniformly form the metal thin film layer, and includes a material selected from the group consisting of polyhydric alcohols including an ethylene glycol, a diethylene glycol, a propylene glycol, butanediol or pentanediol, ascorbic acid, glycine, di-malic acid, sodium tartrate, ammonium acetate, and combinations thereof.

In an embodiment of the present disclosure, the reducing agent used in the step (b) is a strong reducing agent as well as a dedoping agent for the conductive polymer, and includes a material selected from the group consisting of ammonia water, sodium hydroxide, sodium hypophosphite (NaH₂PO₂), sodium borohydride, a hydrazine, and combinations thereof.

In an embodiment of the present disclosure, an ultrasonic treatment in the step (b) may be intermittently performed.

In an embodiment of the present disclosure, the conductive polymer includes a conductive polymer selected from the group consisting of a polyaniline, a polypyrrole, a polythiophene, poly(3,4-ethylenedioxythiophene), a polyacetylene, and combinations thereof.

In an embodiment of the present disclosure, the conductive polymer may include a polyaniline and includes, for example, a conductive polymer selected from the group consisting of a polyaniline emeraldine base (EB), a polyaniline emeraldine salt (ES), and combinations thereof. For example, the conductive polymer may include a polyaniline emeraldine base (EB), a polyaniline emeraldine salt (ES), or all of them depending on the doping state, but may not be limited thereto. In an embodiment of the present disclosure, the metal includes a metal selected from the group consisting of copper, nickel, palladium, ruthenium, tin, lead, iron, stainless steel, gold, silver, and combinations thereof. For example, the metal may include copper as a main component, but may not be limited thereto.

In an embodiment of the present disclosure, the metal salt precursor includes a salt selected from the group consisting of a sulfate, chloride, nitrate, acetate, or cyanide of copper, nickel, tin, lead or iron, and combinations thereof.

In an embodiment of the present disclosure, a copper salt precursor serving as the metal salt precursor may include a member selected from the group consisting of copper sulfate, copper(I) chloride, copper(II) chloride, copper(II) nitrate, copper(II) acetate, copper carbonate, copper(II) cyanide, copper iodide, and combinations thereof.

In an embodiment of the present disclosure, an aspect ratio of the conductive polymer structure is from about 1 to about 1,000. For example, the aspect ratio of the conductive polymer structure may be adjusted according to the equivalence ratio of a solvent system, monomers, and a polymerization initiator used when preparing an individual structure such as a conductive polymer particle. For example, the aspect ratio of the conductive polymer structure may be from about 1 to about 1,000, from about 10 to about 1,000, from about 50 to about 1,000, from about 100 to about 1,000, from about 200 to about 1,000, from about 300 to about 1,000, from about 400 to about 1,000, from about 500 to about 1,000, from about 600 to about 1,000, from about 700 to about 1,000, from about 800 to about 1,000, from about 900 to about 1,000, from about 1 to about 900, from about 1 to about 800, from about 1 to about 700, from about 1 to about 600, from about 1 to about 500, from about 1 to about 400, from about 1 to about 300, from about 1 to about 200, from about 1 to about 100, from about 1 to about 50, or from about 1 to about 10. Further, the conductive polymer structure may have all possible shapes such as spherical shape, oval shape, rod shape, nanorod shape, nanoneedle shape, nanofiber shape, and the like.

In an embodiment of the present disclosure, a thickness of the metal thin film is from about 1 nm to about 300 nm. For example, the thickness of the metal thin film may be from about 1 nm to about 300 nm, from about 10 nm to about 300 nm, from about 20 nm to about 300 nm, from about 40 nm to about 300 nm, from about 60 nm to about 300 nm, from about 80 nm to about 300 nm, from about 100 nm to about 300 nm, from about 120 nm to about 300 nm, from about 140 nm to about 300 nm, from about 160 nm to about 300 nm, from about 180 nm to about 300 nm, from about 200 nm to about 300 nm, from about 220 nm to about 300 nm, from about 240 nm to about 300 nm, from about 260 nm to about 300 nm, from about 280 nm to about 300 nm, from about 1 nm to about 280 nm, from about 1 nm to about 260 nm, from about 1 nm to about 240 nm, from about 1 nm to about 220 nm, from about 1 nm to about 200 nm, from about 1 nm to about 180 nm, from about 1 nm to about 160 nm, from about 1 nm to about 140 nm, from about 1 nm to about 120 nm, from about 1 nm to about 100 nm, from about 1 nm to about 80 nm, from about 1 nm to about 60 nm, from about 1 nm to about 40 nm, from about 1 nm to about 20 nm, or from about 1 nm to about 10 nm. Further, about 70% or more of all the hybrid structures may be coated with the metal layer having a thickness of from about 1 nm to about 300 nm.

In an embodiment of the present disclosure, the metal thin film layer is coated partly or entirely on the surface of the conductive polymer structure. For example, the metal thin film layer may be coated on from about 30% to about 100% of the surface of the hybrid structure. For example, the metal thin film layer may be coated on from about 30% to about 100%, from about 35% to about 100%, from about 40% to about 100%, from about 45% to about 100%, from about 50% to about 100%, from about 55% to about 100%, from about 60% to about 100%, from about 65% to about 100%, from about 70% to about 100%, from about 75% to about 100%, from about 80% to about 100%, from about 85% to about 100%, from about 90% to about 100%, from about 95% to about 100%, from about 30% to about 95%, from about 30% to about 90%, from about 30% to about 85%, from about 30% to about 80%, from about 30% to about 75%, from about 30% to about 70%, from about 30% to about 65%, from about 30% to about 60%, from about 30% to about 55%, from about 30% to about 50%, from about 30% to about 45%, from about 30% to about 40%, or from about 30% to about 35% of the surface of the hybrid structure.

In an embodiment of the present disclosure, the metal thin film layer has oxidation resistance and/or corrosion resistance at a high temperature of about 100° C. or more, about 150° C. or more, about 200° C., about 250° C. or more, or about 300° C. or more.

In an embodiment of the present disclosure, as inherently conducting polymer (ICP) particles, a polyaniline, a polypyrrole, a polythiophene, PEDOT, a polyacetylene, and the like are well known as inherently conducting polymer (ICP) particles. Herein, polyaniline which is the cheapest and stable in air will be selected to disclose the preparation method, but the present disclosure may not be limited thereto.

In an embodiment of the present disclosure, the conductive polymer particles may be prepared by polymerizing a polymer, dissolving the polymer in a proper solvent, and performing electrospinning, or may be prepared by an in-situ method in which the shape of a polymer is determined at the same time when polymerization is carried out. Herein, the in-situ method will be described, but the present disclosure may not be limited thereto.

In an embodiment of the present disclosure, the water-organic interface is prepared and polymerization is induced on the interface, and the shape, i.e., the aspect ratio, of a particle is determined depending on the relative volume ratio of water and an organic layer, the relative ratio of an initiator and monomers, the acidity (pH) of a medium, the polymerization temperature, the reaction time, and the like. Further, since an inorganic acid such as hydrochloric acid or a functional organic acid such as DBSA is used, even if polymerization is carried out by various methods, the reaction occurs in an acidic medium, and, thus, an emeraldine salt (ES) can be obtained. When the ES is dedoped with ammonia water or the like, it is converted into emeraldine base (EB). The present disclosure may not be limited to conductive polymers, such as ES or EB, in a specific oxidation state.

Herein, a polymerization reactor is made of a polymerization tank and a polymerization inducing tank, and a reaction medium and conditions are selected for each of a case 1) where a functional organic acid is used as a dopant and a case 2) where an inorganic acid is used as a dopant depending on the types of an aniline monomer, its derivative, and dopant. The reactants and the reactor are configured to increase the effect of the present disclosure and can be described in detail as follows.

Organic Acid Used as Dopant

A hydrophobic organic solvents such as chloroform, toluene, xylene, or hexane is put into the polymerization tank, and monomers of an aniline or its derivative and a dopant are dissolved in the solvent. A hydrophilic acidic aqueous solution including an initiator and a dopant is put into the polymerization inducing tank to serve as a reaction medium. A dropping funnel is used to add dropwisely the solution in the polymerization inducing tank into the polymerization tank, and after the reaction, washing and filtration is performed to obtain a conductive polymer.

Inorganic Acid Used as Dopant

A solution in which monomers of an aniline or its derivative are dissolved in an organic solvent and an acidic aqueous solution in which a dopant is dissolved are mixed at a proper ratio in the polymerization tank to form a heterogeneous phase. An aqueous solution including an initiator and a dopant is put into the polymerization inducing tank to serve as a reaction medium. A dropping funnel is used to add dropwisely the solution in the polymerization inducing tank into the polymerization tank, and after the reaction, washing and filtration is performed to obtain a conductive polymer. The shapes and sizes of polyaniline particles produced in the polymerization tank are affected by the relative volume ratio of the hydrophilic layer and the hydrophobic layer forming the interface. The interfaces are prepared to form spherical particles (if any one phase has a volume ratio of less than about 15%), rod-shaped particles (if any one phase has a volume ratio of from about 25% to about 40%), and plate-shaped particles (if any one phase has a volume ratio of from about 40% to about 60%), and polymerization is carried out on these interfaces. The aspect ratio of the particles is affected by the relative molar ratio of the monomers and the initiator, pH, the stirring speed, the shape of an impeller, and the reaction temperature. As the concentration ratio of the monomers increases and as the pH decreases, the shapes of the particles can be regulated more easily. It is desirable to suppress secondary growth by regulating the stirring speed.

These conductive polymers may be doped or dedoped by an electric method or acid-base reaction. Particularly, the conductivity of polyaniline can be regulated by acid-base reaction, and, thus, polyaniline has been widely used. Two nitrogen atom groups —NH₂+ and —NW included in the skeleton of the polyaniline have pKa values of 2.5 and 5.5, respectively. Therefore, a strong acid with pKa<2.5 may give protons to these two groups and can be used for doping. An imine nitrogen atom can be entirely or partly added with protons by a protonic acid aqueous solution. Thus, a doping level can be regulated, and when an equivalent ratio reaches 1:1, an emeraldine salt (ES) can be obtained. The electrical conductivity of the ES increases rapidly from about 10⁻⁸ S/cm to about 1 S/cm or to about 1,000 S/cm depending on the doping level.

Herein, the protonic acid serving as a dopant imparting conductivity may include a member selected from the group consisting of hydrochloric acid, sulfuric acid, nitric acid, boron hydrofluoric acid, perchloric acid, amidosulfuric acid, an organic acid, benzenesulfonic acid, p-toluenesulfonic acid, m-nitrobenzoic acid, trichloroacetic acid, acetic acid, propionic acid, hexanesulfonic acid, octanesulfonic acid, 4-dodecylbenzenesulfonic acid, 10-camphorsulfonic acid, ethylbenzenesulfonic acid, p-toluenesulfonic acid, o-anisidine-5-sulfonic acid, p-chlorobenzenesulfonic acid, hydroxybenzenesulfonic acid, trichlorobenzenesulfonic acid, 2-hydroxy-4-methoxybenzophenonesulfonic acid, 4-nitrotoluene-2-sulfonic acid, dinonylnaphthalenesulfonic acid, 4-morpholineethanesulfonic acid, methanesulfonic acid, ethanesulfonic acid, trifluoromethanesulfonic acid, C₈F₁₇-sulfonic acid, 3-hydroxypropanesulfonic acid, dioctylsulfosuccinate, 3-pyridinesulfonic acid, p-polystyrenesulfonic acid, and combinations thereof, but may not be limited thereto.

As a polymeric acid, a polystyrenesulfonic acid, a polyvinylsulfonic acid, a polyvinylsulfuric acid, a polyamic acid, a polyacrylic acid, a cellulose sulfonic acid, a polyphosphoric acid, or the like may be used. However, the present disclosure may not be limited thereto. These acids may be used alone or as a mixture of two or more of them.

The metal thin film can be coated entirely or partly on the surface of the conductive polymer by physical vapor deposition including sputtering and electro plating and electroless plating. In either case it may be needed that, the metal thin film layer may be regulated to have a proper thickness. The electroless plating may include a chemical method of forming a metal thin film partly or entirely on surface using a strong reducing agent or a weak reducing agent serving as a solvent at room temperature. Herein, only the chemical method will be described, but the present disclosure may not be limited thereto. The chemical method is easy to control at the atomic and molecular levels and effective for mass production requiring the scaling-up of processes.

Kurihara et al. (Nanostructured Materials, vol. 5, No 6, pp607-613, 1995 and U.S. Pat. No. 5,759,230) reported a catalyst-free chemical method capable of coating a metal on various substrates at from about 140° C. to about 190° C. using micro metal particles in polyol such as ethylene glycol which is a weak reducing agent. This polyol method, called hydrothermal synthesis, uses a compound having two or more alcohol groups to reduce metal ions and forms a metal thin film on surface, and polyols including an ethylene glycol, a diethylene glycol, a propylene glycol, butanediol, and pentanediol may be properly used as a solvent and as a weak reducing agent.

Depending on the kind of a metal salt which is a precursor, subsidiary additives such as a nucleation agent and a complexing agent for enhancing the surface wettability and adhesion may be used, in addition to the reducing agent. These additives become obstacles during a sintering process and thus need to be removed because they cause an increase in sintering temperature. Particularly, when nanoscale metal particles of from about 1 nm to about 100 nm are prepared, a steric stabilizer such as a surfactant may be used to suppress the agglomeration of the metal and enhance the solubility of the precursor. These stabilizers are sensitive to a change in pH, and, thus, the pH of the reaction system needs to be regulated during reduction. In the present disclosure, a polyvinylpyrrolidone (PVP) capable of controlling surface properties by stabilizing the surface of colloid particles and serving as a surfactant may be used at a concentration of from about 0.05 M to about 10 M (w/w) relative to metal ions. In this case, the produced particles are fine with a size of about 50 nm or less and thus can be produced into an ink to implement a conductive micro pattern and can also be used for a display bezel electrode, a high-performance RFID, solar cell, and the like.

When the metal thin film is coated, ascorbic acid, glycine, di-malic acid, sodium tartrate, or ammonium acetate which is a weak reducing agent to assist to uniformly form the metal thin film layer in a third step of reducing the metal salt precursor to coat a film may be used in addition to the steric stabilizer.

In the present disclosure, copper is suitable as a metal of a surface metal thin film. Copper is cheap and has high conductivity and thus is very useful. However, as copper decreases in size to nanoscale, it can be easily oxidized in air. Therefore, copper is very limited in use, and, thus, it is possible to maximize the effect of the present disclosure. A metal salt used as a copper precursor may be selected from copper sulfate, copper(I) chloride, copper(II) chloride, copper(II) nitrate, copper(II) acetate, copper carbonate, copper(II) cyanide, copper iodide, and combinations thereof. The metal thin film is coated partly or entirely depending on the concentration of the metal salt. Therefore, a suitable concentration of the metal salt may be from about 0.01 M to about 1 M relative to the conductive polymer particles having relative large particle pore surfaces and the concentration of ethylene glycol may be from about 1 M to about 10 M. In some cases, the concentration of the metal salt may increase to about 100 times the concentration of ethylene glycol.

In the present disclosure, coating is performed in two steps. First, a metal precursor is dissolved in a solvent and conductive polymer particles are put into the solution, followed by ultrasonic stirring to facilitate good wetting. Then, a reducing agent is added and reacted for from about 10 minutes to about 5 hours. Typical reaction conditions will be described in detail in the following Examples. Relatively large particles of micrometer size may be prepared to produce a composite material by plastic extrusion and injection molding or to implement conductivity by sintering, or particles of nanometer size may be prepared to be used as an ink by dispersion, and the composition of compounds to be added may vary depending on the use.

### MODE FOR CARRYING OUT THE INVENTION

Hereinafter, the present disclosure will be explained in more detail with reference to Examples. However, the following Examples are illustrative only for better understanding of the present disclosure but do not limit the present disclosure.

### EXAMPLES

### Example 1: Preparation of Polyaniline EB and ES

A cooling circulator was installed in a 1-L double jacket reactor, and 60 mL of 1 M hydrochloric acid solution was put into the reactor and 0.025 M (4 mL) aniline monomer was added thereto, followed by well stirring at 10° C. for 1 hour. Then, 300 mL of chloroform was added thereto and dispersed. In this case, an aniline monomer-chloric acid salt served as a surfactant, and a stable first solution was prepared. A second solution was prepared by dissolving and stirring 5.7 g (0.025 M) of ammonium persulfate (APS) serving as an initiator in 125 mL of 1M HCl for 1 hour. The second solution was added dropwise into the first solution for 1 hour with stirring at 300 rpm. After all the second solution was added into the first solution, the reaction continued further for 1 hour and then ended. The reaction product was filtered through 2 μm filter paper. The produced polyaniline particles in an ES state were washed 3 times with 1 M chloric acid solution and then washed with methanol and water until the filtrate became colorless and then converted into an EB state by stirring in 150 mL of 1 M ammonia water for 24 hours. The resultant product was filtered and dried in a vacuum oven at 50° C. for 24 hours or more to obtain an aniline polymer EB.

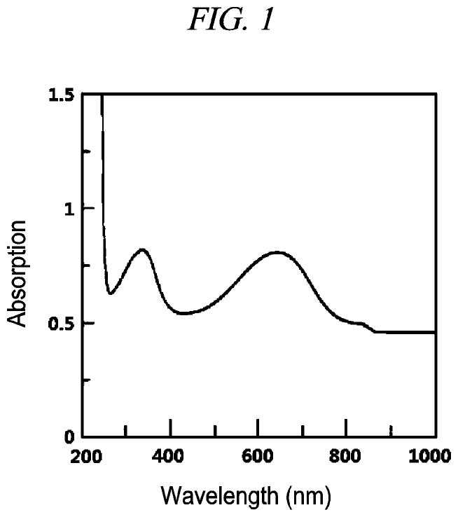

The synthesized EB was dissolved in 1-N-methyl-2-pyrrolidinone (NMP) to prepare a 2% solution, and then UV-vis-NIR spectroscopy was performed. Two characteristics absorption peaks at 328 nm and 635 nm as shown in FIG. 1 were caused by π-π* and exciton transition, respectively, of the EB. Thus, the EB structure can be seen.

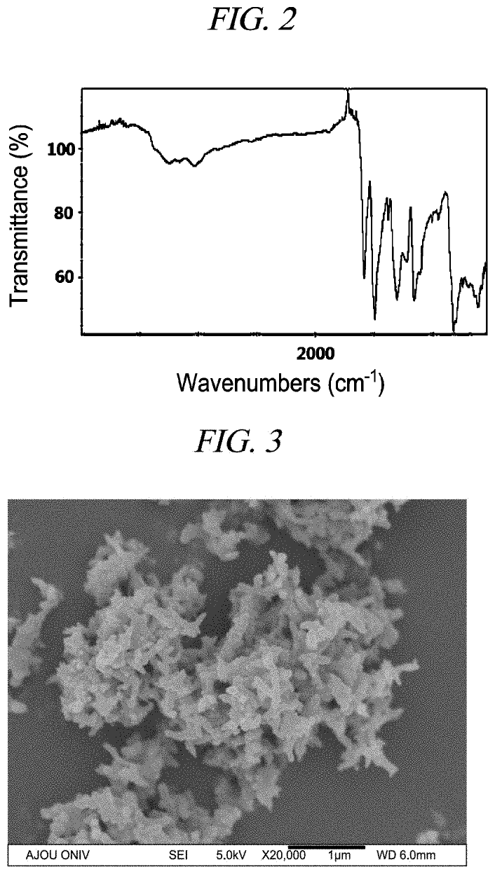

FIG. 2 is an infrared spectroscopy spectrum of the synthesized EB. Absorption peaks at 827 cm⁻¹, 1150 cm⁻¹, 1320 cm⁻¹, 1501 cm⁻¹, and 1591 cm⁻¹ are characteristic peaks of the EB, and an aromatic C—H in-plane bending peak at from 1,170 cm⁻¹ to 1,000 cm⁻¹, a C—H out-of-plane bending peak at 830 cm⁻¹, and two strong absorption peaks at 1,501 cm⁻¹ and 1,592 cm⁻¹ corresponded to C═C and C═N vibration modes of benzenoid and quinoid rings. A ratio of these peaks was about 0.9, which confirms that emeraldine EB in a base state was synthesized.

### Example 2: Synthesis of Rod-Shaped ES/AMPSA

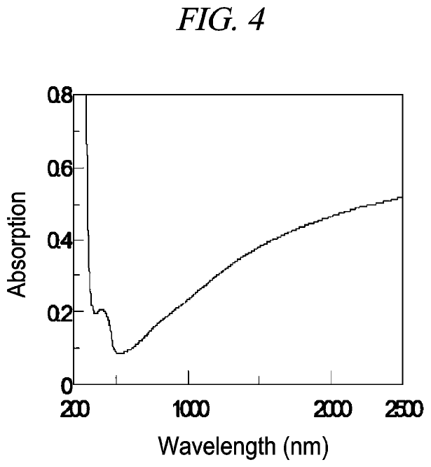

Polymerization was carried out in the same manner as in Example 1 except that 150 mL of AMPSA aqueous solution was used instead of 60 mL of chloric acid solution. To suppress secondary growth of the polymer at the early state of reaction, interfacial polymerization was induced while the reaction speed was regulated carefully. The synthesized precipitate was filtered and washed several times with methanol and water and then filtered to directly obtain ES particles. Referring to a scanning electron microscope (SEM) image shown in FIG. 3, it can be seen that rod-shaped particles having an aspect ratio of from 5 to 10 were synthesized. FIG. 4 is a UV-vis spectrum obtained by dissolving particles in an ES state in trifluoroethanol and conducting spectroscopy. It is known that a peak around 420 nm and an absorption in a near-IR region were caused by a polaronic peak and a free-carrier tail, respectively. The synthesized polyaniline emeraldine salt had a band gap of 4.0 eV and a relatively low ionization energy of 5.1 eV. Thus, when doped with acid, electrons are desorbed and moved to a conduction band and thus carry an electric current. In FIG. 4, a continuous increase in near-IR absorbance along with an increase in wavelength means that doping was performed well and a microstructure with high mobility of electrons was prepared. Therefore, the ES prepared according to the present disclosure has high corrosion resistance and when a metal film is coated partly on surface of these particles, the metal can reflect and absorb electromagnetic waves at the same time, and, thus, it is possible to effectively shield electromagnetic waves.

### Example 3: Observation of Polyaniline Particle Shape

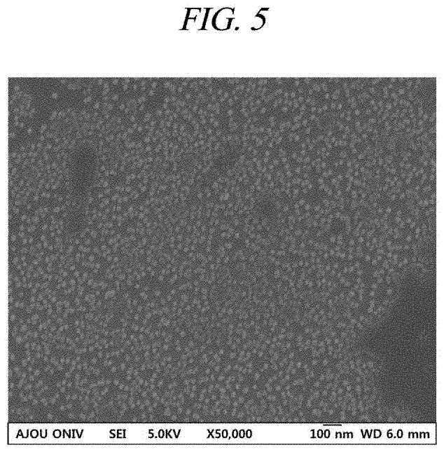

Zirconia balls (1 mm, 1 kg) and 10 g of EB powder were put into an ethylene glycol solvent and then spun for 24 hours. After filtering of the zirconia balls, the reaction product was separated with a centrifuge at 7,000 rpm for 10 minutes, and then a precipitate was collected and dried in a vacuum oven at 50° C. for 24 hours or more to obtain EB powder. The EB powder was scanned with a SEM to check the shapes and sizes of particles. FIG. 5 shows spherical nanoparticles having a size of from 30 nm to 70 nm.

### Example 4: Pretreatment of EB and ES Particles

It is important to pretreat conductive polymer particles before coating. If the conductive polymer particles are pretreated with a complexing agent such as chromic acid, polyethylene glycol, SnCl₂, PdCl₂, and glycine, it is possible to more uniformly perform coating to a controllable thickness. Before coating, a metal salt solution is induced to uniformly wet surface of the particles by ultrasonic stirring (at 100 W and a frequency of from 40 kHz to 60 kHz) with sufficient stirring until no air remains inside pores. Then, 0.1 g/ml of polyethylene glycol (PEG) was dissolved in distilled water selected as a dispersion medium and EB or ES particles were added thereto, followed by stirring and washing with ultrasonic waves for 5 minutes and centrifugal collection. This process was repeated 3 times, and then pretreatment was performed with SnCl₂ at a concentration of 0.1 g/100 ml per 1 g of the conductive polymer for 3 minutes and with PdCl₂ for 30 minutes.

### Example 5: Metal Film Coating, Polyol Method

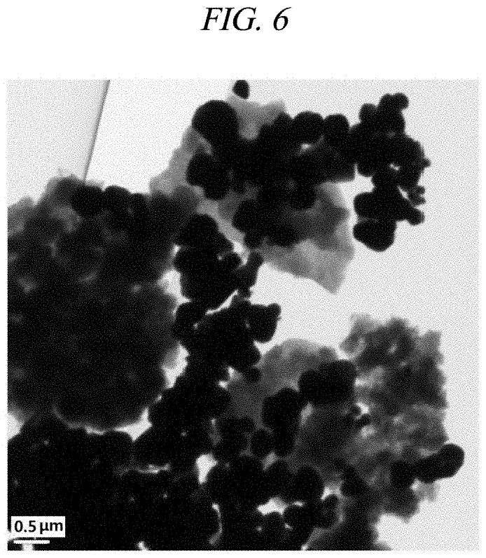

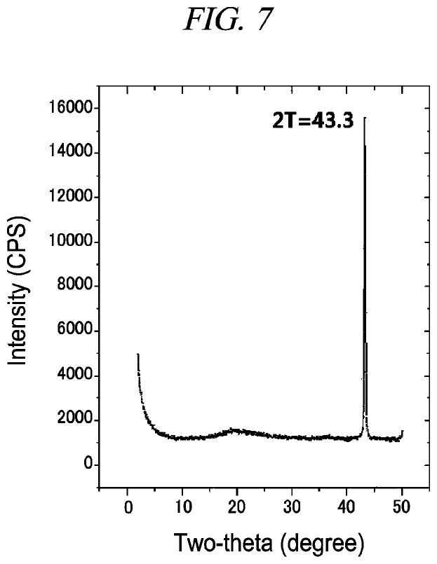

0.50 g of EB particles prepared according to Example 4 was put into 200 g of ethylene glycol and then dispersed using ultrasonic waves for 1 hour. 5 mmol copper diacetate, which is a metal salt, was dissolved in 200 g of ethylene glycol for 10 minutes, and then the solution was added dropwise to an EB solution dispersed in ethylene glycol, followed by stirring at 160° C. for 1 hour. After the reaction, the reaction product was filtered through 2 μm filter paper. The filtrate was dried in a vacuum oven at 50° C. for 24 hours or more to obtain copper-PANI hybrid complex. A transmission electron microscope (TEM) image (FIG. 6) and an X-ray diffraction diagram (FIG. 7) of these particles are shown. Spherical particles coated with a copper having a size of less than 500 nm appear bunches of grapes. The X-ray diffraction diagram also confirms the presence of complex peaks. An amorphous broad peak 2 Θ20° indicates an EB and a strong peak around 43° indicates the crystal plane (111) of a copper atom.

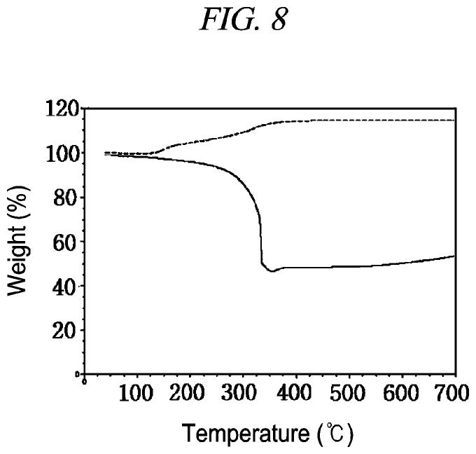

Thermal stability of the copper thin film on the surface of the prepared particles was examined by a thermogravimetric analysis (TGA) method. Referring to FIG. 8, it can be seen that copper nanoparticles without treatment with the conductive polymer increase in weight at from 150° C. and increase again in weight around 300° C., which shows that oxidation occurs in at least two steps. However, the hybrid particles of the present example did not show an increase in weight even at 300° C. This means oxidation resistance is maintained even at 300° C.

### Example 6: Strong Reducing Agent Method

A strong reducing agent is selected from ammonia water, sodium hydroxide, sodium hypophosphite (NaH₂PO₂), sodium borohydride (NaBH₄), hydrazine (N₂H₄H₂O), potassium bromide, NaCl, and combinations thereof. These reducing agents induce dedoping of the conductive polymer particles, increase the compatibility in an aqueous solution to increase the dispersibility, and also improve thermal resistance of the particles. First, 0.30 g of ES particles synthesized according to Example 1 were well wetted with 100 mL of ammonia water in a beaker. This solution and a solution in which 0.56 g of copper nitrate was dissolved in 100 mL of water were put into the reactor and stirred for 1 hour, and then 0.91 g of sodium borohydride was added thereto, followed by stirring for 1 hour. When the reaction solution turned from dark brown to black and the reaction was completed, the reaction product was filtered and dried to obtain a hybrid complex.

### Example 7: Comparative Test

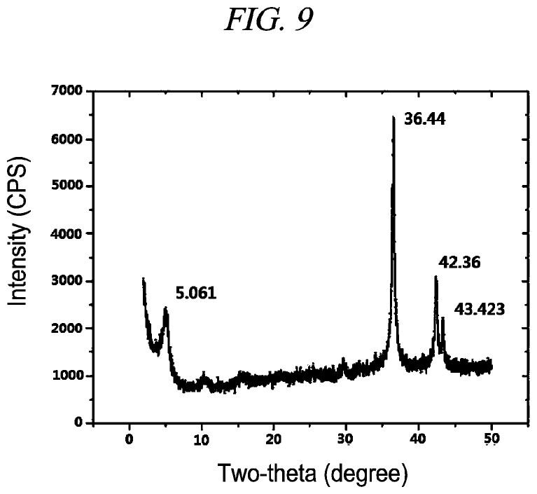

A comparative test was conducted by covering metal particles with a conductive polymer to suppress corrosion according to a conventional method. N-methylpyrrolidone (NMP), chloroform, trifluoroethanol, N,N-dimethylformamide (DMF), and the like may be used as an organic solvent to dissolve polyaniline. The sample synthesized according to Example 2 was dissolved in a trifluoroethanol solvent and copper particles having a diameter of 20 nm were added thereto, followed by stirring, filtration by centrifugation, and drying. An X-ray diffraction test was performed to the reaction product. Referring to an X-ray diffraction diagram shown in FIG. 9, oxidized copper (Cu₂O, 36.4° and 38°) shows much stronger peaks than non-oxidized copper atoms (2 Θ, 43.2°). It can be seen that a method of coating a conductive polymer polymerized by an in-situ method or synthesized and prepared in a solution state with nanoscale metal particles is not effective in suppressing corrosion.

### Example 8: Sintering Test

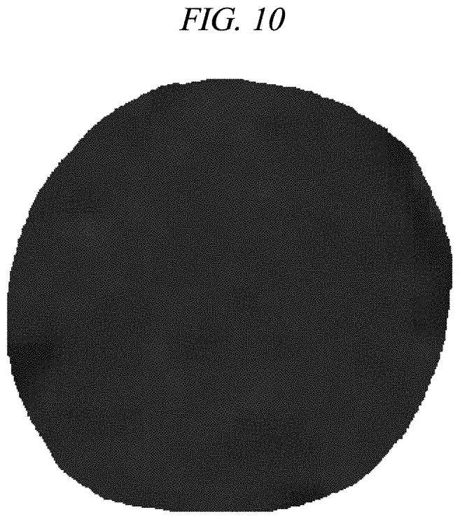

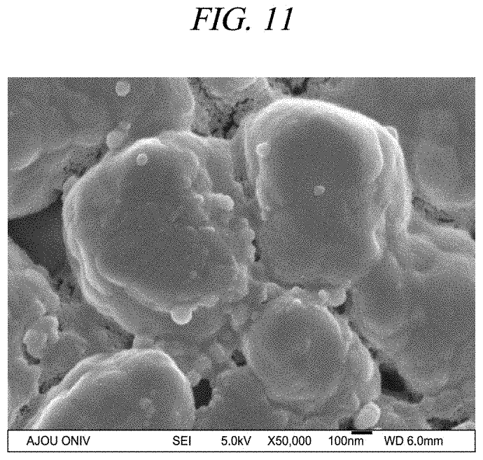

Hybrid particles of the present disclosure prepared according to Example 5 are stable even at 300° C. Thus, sintering was performed using a hot press at 300° C. for 1 hour. FIG. 10 and FIG. 11 show the shape and a FE-SEM image of the sample. The photo of the sample shows a sintered part where copper color is seen and also shows that the surface copper layer was not oxidized and remained as pure copper, and the FE-SEM image shows that necking occurred in the surface copper layer and thus the metal particle thin films were connected to each other.

The above description of the present disclosure is provided for the purpose of illustration, and it would be understood by a person with ordinary skill in the art that various changes and modifications may be made without changing technical conception and essential features of the present disclosure. Thus, it is clear that the above-described examples are illustrative in all aspects and do not limit the present disclosure. For example, each component described to be of a single type can be implemented in a distributed manner. Likewise, components described to be distributed can be implemented in a combined manner.

The scope of the present disclosure is defined by the following claims rather than by the detailed description of the embodiment. It shall be understood that all modifications and embodiments conceived from the meaning and scope of the claims and their equivalents are included in the scope of the present disclosure.

1. A hybrid structure, comprising a metal thin film layer coated on a surface of a conductive polymer structure,
wherein the hybrid structure imparts enhancement in oxidation resistance and/or corrosion resistance of the metal.

2. The hybrid structure of claim 1,
wherein the conductive polymer of the a conductive polymer structure includes a conductive polymer selected from the group consisting of a polyaniline, a polypyrrole, a polythiophene, poly(3,4-ethylenedioxythiophene), a polyacetylene, and combinations thereof.

3. The hybrid structure of claim 1,
wherein an aspect ratio of the conductive polymer structure is from 1 to 1,000.

4. The hybrid structure of claim 1,
wherein the conductive polymer includes a conductive polymer selected from the group consisting of a polyaniline emeraldine base (EB), a polyaniline emeraldine salt (ES), and combinations thereof.

5. The hybrid structure of claim 1,
wherein the metal includes a metal selected from the group consisting of copper, nickel, palladium, ruthenium, tin, lead, iron, stainless steel, gold, silver, and combinations thereof.

6. (canceled)

7. The hybrid structure of claim 1,
wherein a thickness of the metal thin film is from 1 nm to 300 nm.

8. The hybrid structure of claim 1,
wherein the metal thin film layer is coated partly or entirely on the surface of the conductive polymer structure.

9. The hybrid structure of claim 1,
wherein the metal thin film layer has oxidation resistance at a high temperature of 100° C. or more.

10. A conductive ink filler, comprising the hybrid structure according to claim 1,
wherein the hybrid structure includes the metal thin film layer coated on the surface of the conductive polymer structure for enhancing oxidation resistance and/or corrosion resistance of the metal.

11. A conductive plastic composite material, comprising the hybrid structure according to claim 1 as a conductive filler,
wherein the hybrid structure includes the metal thin film layer coated on the surface of the conductive polymer structure for enhancing oxidation resistance and/or corrosion resistance of the metal.

12. A fuel cell separator, comprising the conductive plastic composite material according to claim 11.

13. An electrode, comprising the hybrid structure according to claim 1,
wherein the hybrid structure includes the metal thin film layer coated on the surface of the conductive polymer structure for enhancing oxidation resistance and/or corrosion resistance of the metal.

14. An electromagnetic shielding agent, comprising the hybrid structure according to claim 1,
wherein the hybrid structure includes the metal thin film layer coated on the surface of the conductive polymer structure for enhancing oxidation resistance and/or corrosion resistance of the metal.

15. A method for preparing a hybrid structure, comprising:
(a) forming a conductive polymer structure; and
(b) coating a metal on a surface of the conductive polymer structure by an electroless plating method for reducing a metal salt precursor using a solution containing the conductive polymer structure, the metal salt precursor, a reducing agent and a dispersion solvent to obtain the hybrid structure including a metal thin film layer coated on the surface of the conductive polymer structure.

16. The method for preparing a hybrid structure of claim 15, further comprising pretreating the conductive polymer structure before the step (b).

17. The method for preparing a hybrid structure of claim 16,
wherein a material used for the pretreating of the conductive polymer structure includes a material selected from the group consisting of a polyethylene glycol, a sodium polyacrylate, a polyvinylpyrrolidone, a poly(vinyl caprolactam), a poly(sodium 4-styrenesulfonate), SnCl₂, PdCl₂, and combinations thereof.

18. The method for preparing a hybrid structure of claim 15,
wherein the reducing agent used in step (b) is a weak reducing agent to assist to uniformly form the metal thin film layer, and includes a material selected from the group consisting of polyhydric alcohols including an ethylene glycol, a diethylene glycol, a propylene glycol, butanediol or pentanediol, ascorbic acid, glycine, di-malic acid, sodium tartrate, ammonium acetate, and combinations thereof.

19. The method for preparing a hybrid structure of claim 15,
wherein the reducing agent used in the step (b) is a strong reducing agent as well as a dedoping agent for the conductive polymer, and includes a material selected from the group consisting of ammonia water, sodium hydroxide, sodium hypophosphite (NaH₂PO₂), sodium borohydride, a hydrazine, and combinations thereof.

20. (canceled)

21. The method for preparing a hybrid structure of claim 15,
wherein the conductive polymer includes a conductive polymer selected from the group consisting of a polyaniline emeraldine base (EB), a polyaniline emeraldine salt (ES), and combinations thereof.

22. (canceled)

23. The method for preparing a hybrid structure of claim 15,
wherein the metal salt precursor includes a salt selected from the group consisting of a sulfate, chloride, nitrate, acetate, cyanide or iodide of copper, nickel, tin, lead or iron, and combinations thereof.

24-26. (canceled)
